(19) United States
(12) Patent Application Publication
(10) Pub. No.: US 2005/0218973 A1
(43) Pub. Date: Oct. 6, 2005

(54) Bandwidth adaptation rule for adaptive noise filter for inverse filtering with improved disturbance rejection bandwidth and speed

(76) Inventor: Mirsad Halimic, Surrey (GB)

Correspondence Address: RATNERPRESTIA, P O BOX 980, VALLEY FORGE, PA, 19482-0980, US

(21) Appl. No.: 10/516,275

(22) PCT Filed: May 30, 2003
(86) PCT No.: PCT/GB03/02388

§ 371 Date: Nov. 29, 2004

(30) Foreign Application Priority Data
May 31, 2002 (GB) 0212776.9
May 31, 2002 (GB) 0212778.5

(51) Int. Cl. H03B 1/00

(52) U.S. Cl. 327/552

(57) ABSTRACT

In digital communications, a considerable effort has been devoted to neutralise the effect of channels (i.e., the combination of transmit filters, media and receive filters) in transmission systems, so that the available channel bandwidth is utilised efficiently. The objective of channel neutralisation is to design a system that accommodates the highest possible rate of data transmission, subject to a specified reliability, which is usually measured in terms of the error rate or average probability of symbol error. An equaliser normally performs neutralisation of any disturbances the channel may introduce by malting the overall frequency response function T(z) to be flat. Since a channel is time varying, due to variations in a transmission medium, the received signal is nonstationary. Therefore, an adaptive equaliser is utilised to provide control over the time response of a channel. Since an adaptive equaliser is an inverse system of a channel, it amplifies the frequency of noise outside the bandwidth of a channel. In order to reduce the effect of noise, a low pass filter is cascaded with the equaliser. However, the cascaded filter can introduce a negative impact on the speed of adaptation. Therefore, the bandwidth of the cascaded filter is chosen to be very wide at the beginning of the adaptation process. This way, the output reaching the static value will not be delayed. As the output of the adaptive filter is close to the static value, the bandwidth decreases to cancel the effect of noise. The adaptive rule for noise filter can be defined as (I). The constants α and β depend on the level of noise and are chosen by trial and error method. Δ is a variable that is used to change the value of τ and consequently the bandwidth of the filter. Δ acts as an input to the proportional controller. Furthermore, in the same equation, β represents a proportional (P) controller gain (Kₚ). In order to reduce the disturbance rejection bandwidth, improve speed, resonant frequency and rectify a potential problem, an integral (I) control mode and a differential (D) control mode are proposed to be added to the existing proportional control mode.

The present invention relates to the rule for changing the bandwidth of a noise filter.

### BACKGROUND

In digital communications, a considerable effort has been devoted to neutralise the effect of channels (i.e., the combination of transmit filters, media and receive filters) in transmission systems, so that the available channel bandwidth is utilised efficiently. The objective of channel neutralisation is to design a system that accommodates the highest possible rate of data transmission, subject to a specified reliability, which is usually measured in terms of the error rate or average probability of symbol error.

An equaliser normally performs neutralisation of any disturbances the channel may introduce by making the overall frequency response function T(z) to be flat. An equaliser cascaded to a channel is shown in FIG. 1. A channel is cascaded with its inverse system. Ideally, inputs appear in the output without any distortion. Since in reality a channel is time varying, due to variations in a transmission medium, the received signal is nonstationary. Therefore, an adaptive equaliser is utilised to provide control over the time response of a channel.

The characteristic function of channels (i.e., the combination of transmit filters, media and receive filters) is that of a low pass filter. Since an adaptive equaliser is an inverse system of a channel, it amplifies the frequency of noise outside the bandwidth of a channel. In order to reduce the effect of noise, a low pass filter is cascaded with the equaliser. However, the cascaded filter can introduce a negative impact on the speed of adaptation. Therefore, the bandwidth of the cascaded filter is chosen to be very wide at the beginning of the adaptation process. This way, the output reaching the static value will not be delayed. As the output of the adaptive filter is close to the static value, the bandwidth decreases to cancel the effect of noise.

In order to illustrate this philosophy, a first order low pass filter will be considered.

$$Hn ( z ) = \frac{1 - {ⅇ}^{- \frac{T}{τ}}}{1 - {z}^{- 1} {ⅇ}^{- \frac{T}{τ}}} \qquad ( 1 )$$

where T is the sampling period and τ is the filter time constant.

However, the consideration presented applies to the higher order low pass filters too. Therefore equation 1 becomes:

$$Hn ( z ) = \frac{1 - {ⅇ}^{- \frac{T}{τ}}}{{( 1 - {z}^{- 1} {ⅇ}^{- \frac{T}{τ}} )}^{n}} \qquad ( 2 )$$

where n=1,2,3, . . . .

The time constant τ bounds the bandwidth of the filter. The lower the values of τ result in a wider bandwidth and vice versa. The adaptive rule for noise filter can be defined as:

$$τ = \frac{1}{α + βΔ} \qquad ( 3 )$$

(see Shi, W. J., White, N. M. and Brignell, J. E. (1993): Adaptive filters in load cell response correction, Sensors and Actuators A, A 37-38:280-285). The constants α and β depend on the level of noise and are chosen by trial and error method. Δ is a variable that is used to change the value of τ and consequently the bandwidth of the filter. There are several ways of determining the Δ, for example, by determining the difference between two successive inputs, i.e. Δ=dₐ(k)−dₐ(k−1). Two other ways are presented in FIG. 2.

Δ decreases in steady state condition and hence the time constant of the noise filter τ increases. This turns out a narrowband noise filter that rejects the noise effectively, which is desirable for steady state condition. In the non steady state condition Δ is large, so the time constant of the noise filter τ is small. This means the output of the adaptive equaliser comes out quickly from the output of the noise filter. Therefore, the adaptive rule can adjust the parameters of the adaptive equaliser.

It is evident from FIG. 2 that Δ is the difference of two successive values and Δ acts as an input to the proportional controller. Furthermore, in the same equation, β represents a proportional (P) controller gain (Kₚ). In order to reduce the offset to an acceptable level, Kₚ has to be tuned to a satisfactory value. Increasing the proportional gain allows shaping of the sensitivity function and hence improves steady-state accuracy and low frequency disturbance rejection. However, by increasing the proportional gain the stability margin is reduced and resonant peaks are magnified. Therefore, there may occur a situation where for stability reasons a proportional gain cannot be increased further and the offset will not be reduced to the acceptable level. Consequently, a noise filter bandwidth will not be reduced to the value determined by α and required steady state accuracy will not be achieved.

### SUMMARY OF THE INVENTION

In order to reduce the disturbance rejection bandwidth, resonant frequency and rectify a potential problem, an integral (I) control mode is proposed to be added to the existing proportional control mode.

Thus, a first aspect of the present invention provides a method for adapting the bandwidth of a filter, the method comprising determining the difference between two successive values of a signal passing through the filter and modifying the bandwidth on the basis of a plurality of control variables including a proportional control variable proportional to said difference between successive values and an integral control variable related to the integral of the difference between successive values.

In another aspect of the invention in order to enable faster adaptation of the bandwidth to sudden change, a derivative (D) control mode is proposed to be added to the existing proportional control mode.

Thus, the present invention also provides a method for adapting the bandwidth of a filter, the method comprising determining the difference between two successive values of a signal passing through the filter and modifying the bandwidth on the basis of a plurality of control variables including a proportional control variable proportional to said difference between successive values and a differential control variable related to the differential of the difference between successive values.

The differential control variable and the integral control variable can be used together.

### BRIEF DESCRIPTION OF THE DRAWINGS

An embodiment of the invention will now be described by way of example only and with reference to the accompanying drawings in which:

FIG. 1 is a channel cascaded with its inverse system as used in the prior art. Ideally, inputs appear in the output without any distortion.

FIG. 2 is an Adaptive filter cascaded with an adaptive bandwidth noise filter as used in the prior art.

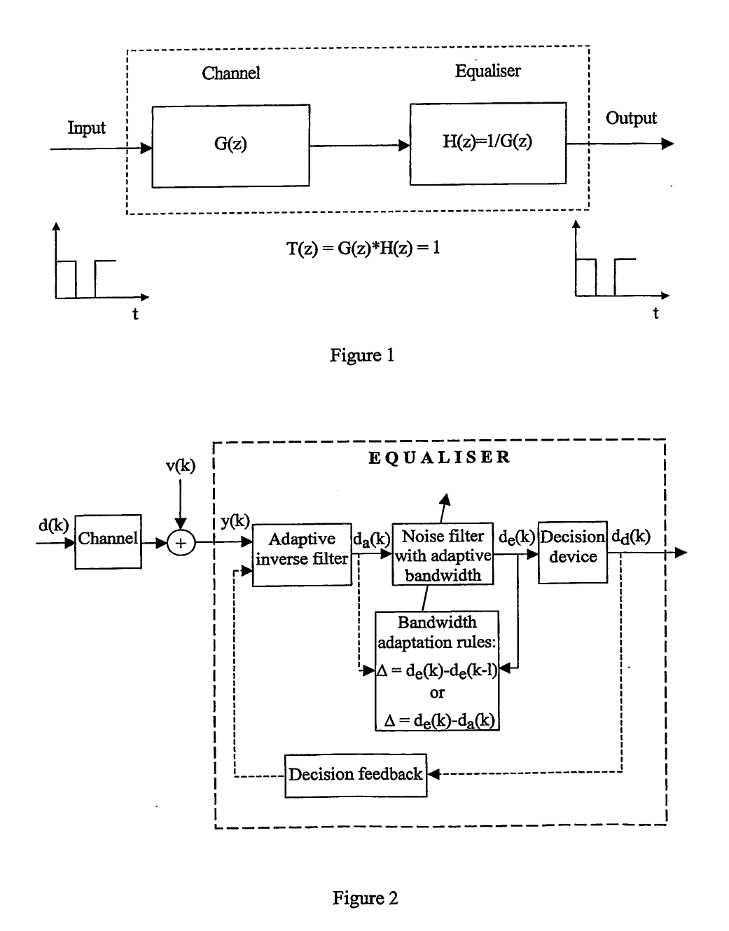

### DESCRIPTION OF THE PREFERRED EMBODIMENT OF THE INVENTION

In the first embodiment of the invention, the aforementioned integral control mode changes it's output by an amount proportional to the integral of the difference of two successive values which intern affects the bandwidth. Consequently, the output will change at a rate proportional to the size of the difference. When combined with the proportional mode, integral mode provides an automatic reset action that eliminates the proportional offset and enables reaching a required filter bandwidth determined by α.

In the second embodiment of the invention, the aforementioned derivative control mode is used in an attempt to anticipate the difference of two successive values by observing the rate of change of the difference and anticipating the next state of the difference accordingly. This enables faster adaptation of a bandwidth to a sudden change in the value of the difference. However, the derivative gain enlarges the disturbance rejection bandwidth and amplifies high frequency change. Therefore, it is always used in combination with P components, where it provides a much “faster” function than a solely proportional law.

In the third embodiment of the invention, the integral control mode and the derivative control mode are used in combination with each other.

In the first embodiment, the proposed adaptive rule for adjusting a bandwidth of noise filter, the product βΔ from the time constant equation 3 is substituted by the following function:

$$χΔ = [ {K}_{p} + \frac{{K}_{i}}{1 - {z}^{- 1}} ] Δ \qquad ( 4 )$$

It will be appreciated that the term KₚΔ represents the aforementioned proportional control variable and

$$\frac{{K}_{i} Δ}{1 - {z}^{- 1}}$$

represents the integral control variable. Thus, χΔ is the sum of these control variables. Therefore, the time constant τ can be defined as:

$$τ = \frac{1}{α + [ {K}_{p} + \frac{{K}_{i}}{1 - {z}^{- 1}} ] Δ} \qquad ( 5 )$$

In the second embodiment, the proposed adaptive rule for adjusting a bandwidth of noise filter, the product βΔ from the time constant equation 3 is substituted by the following function:
χΔ=[Kₚ+(1−z⁻¹)K_{d}]Δ (6)

It will be appreciated that the term KₚΔ represents the aforementioned proportional control variable and (1−z⁻¹)K_{d}Δ represents the differential control variable. Thus, χΔ is the sum of these control variables. Therefore, the time constant τ can be defined as:

$$τ = \frac{1}{α + [ {K}_{p} + ( 1 - {z}^{- 1} ) {K}_{d} ] Δ} \qquad ( 7 )$$

In the third embodiment, the proposed adaptive rule for adjusting a bandwidth of noise filter, the product βΔ from the time constant equation 3 is substituted by the following function:

$$χΔ = [ {K}_{p} + \frac{{K}_{i}}{1 - {z}^{- 1}} + ( 1 - {z}^{- 1} ) {K}_{d} ] Δ \qquad ( 8 )$$

It will be appreciated that the term KₚΔ represents the aforementioned proportional control variable,

$$\frac{{K}_{i} Δ}{1 - {z}^{- 1}}$$

represents the integral control variable and (1−z⁻¹)K_{d}Δ represents the differential control variable. Thus, χΔ is the sum of these control variables. Therefore, the time constant τ can be defined as:

$$τ = \frac{1}{α + [ {K}_{p} + \frac{{K}_{i}}{1 - {z}^{- 1}} + ( 1 - {z}^{- 1} ) {K}_{d} ] Δ} \qquad ( 9 )$$

Because the three gains Kₚ, Kᵢ and K_{d} are adjustable, the proposed adaptive rule can be tuned to provide the desired system response.
Method for Determining Kₚ, Kᵢ and K_{d} Gain Values

The gain values can be determined in two steps.

1. By determining response specifications, the gain values can be tuned by intuitive experimentation. Using the observations stated in Table 1, the values could be engineered to produce a satisfactory response. The system stability and frequency response could be then analysed to verify the gain values, satisfying all possible input signals. Whilst this is the least scientific method of tuning, it is the most common method implemented and can often produce an adequate result.

TABLE 1
Changing the gain values

| Gain | Rise time | Overshoot | Settling time | S—S error |
|---|---|---|---|---|
| Kₚ | Decreases | Increases | No change | Decreases |
| Kᵢ | No change | Increases | Increases | Eliminates |
| K_{d} | Decreases | Decreases | Decreases | No change |

2. Using a simulation package, such as MATLAB (RTM), Kₚ, Kᵢ and K_{d} can be exhaustively investigated to minimise a particular cost. The most popular cost functions are:
a) The Integral of the Absolute value of the Difference (IAD).

$$LAD = \frac{1}{N} {\sum }_{k = 0}^{k = N - 1} \vert Δ ( k ) \vert \qquad ( 10 )$$
IAD weights all differences equally independent of time and hence often results in an oscillatory response with a long settling time.

Although it provides an analytical method of optimising gain values, it may not be the most suitable criterion.
b) The Integral of Time multiplied by the Absolute value of the Difference (ITAD).

$$ITAD = \frac{1}{N} {\sum }_{k = 0}^{k = N - 1} k \vert Δ ( k ) \vert \qquad ( 11 )$$
ITAD addresses this problem and weights the differences to put less emphasis upon the initial difference. However, it cannot be evaluated theoretically (it cannot be described in the frequency domain and so this function must be optimised using a numerical method.

1. A method for adapting the bandwidth of a filter, the method comprising:
determining a difference between two successive values of a signal passing through the filter; and
modifying the bandwidth on the basis of a plurality of control variables including a proportional control variable proportional to said difference between the successive values and an integral control variable related to the integral of the difference between the successive values.

2. A method as claimed in claim 1 in which the integral control variable is proportional to the integral of the difference between the successive values.

3. A method as claimed in claim 2 in which the integral control variable can be expressed as
$$\frac{{K}_{i} Δ}{1 - {z}^{- 1}}$$
where Δ is the difference between two successive values and Kᵢ is a constant.

4. A method as claimed in claim 1, 2 or 3 wherein the plurality of control variables includes a differential control variable related to the differential of the difference between the successive values.

5. A method for adapting the bandwidth of a filter, the method comprising:
determining a difference between two successive values of a signal passing through the filter; and
modifying the bandwidth on the basis of a plurality of control variables including a proportional control variable proportional to said difference between the successive values and a differential control variable related to a differential of the difference between the successive values.

6. A method as claimed in claim 4 in which the differential control variable is proportional to the differential of the difference between successive values.

7. A method as claimed in claim 6 in which the differential control variable is expressed as
(1−z⁻¹)K_{d}Δ
where Δ is the difference between the two successive values and K_{d} is a constant.

8. A method as claimed in claims 1, 2, 3 or 5 in which the control variables are used to determine a time constant of the filter and the time constant has in inverse relationship with the sum of the control variables.

9. A method as claimed in claim 8 in which the time constant has an inverse relationship with the bandwidth.

10. A method as claimed in claim 9 in which the time constant is defined by the equation
$$τ = \frac{1}{α + χΔ}$$
where τ is the time constant, α is a constant and χΔ is the sum of the control variables.

11. A method as claimed in claims 1, 2, 3 or 5, wherein the two successive values are two successive output values of the filter.

12. A method as claimed in claims 1, 2, 3 or 5 wherein the two successive values are a successive input value and output value of the filter.

13. A method as claimed in claims 1, 2, 3 or 5 wherein the two successive values are two successive input values of the filter.

14. A method as claimed in claims 1, 2, 3 or 5, wherein the filter is a low pass filter.

15. A method as claimed in claim 13, wherein the filter is an n^{th} order low pass filter represented by the equation:
$$Hn ( z ) = \frac{1 - {ⅇ}^{- \frac{T}{τ}}}{{( 1 - {z}^{- 1} {ⅇ}^{- \frac{T}{τ}} )}^{n}}$$
where, T is the sampling period, τ is the time constant, n is the order of the filter and n is a positive integer.

16. A method as claimed in claim 5 in which the differential control variable is proportional to the differential of the difference between successive values.

17. A method as claimed in claim 16 in which the differential control variable is expressed as
(1−z⁻¹)K_{d}Δ
where Δ is the difference between the two successive values and K_{d} is a constant.
